(19) United States
(12) Patent Application Publication
(10) Pub. No.: US 2026/0130273 A1
(43) Pub. Date: May 7, 2026

(54) SEMICONDUCTOR PACKAGE

(71) Applicant: Samsung Electronics Co., Ltd., Suwon-si (KR)

(72) Inventors: Joohee Jang, Suwon-si (KR); Hojin Lee, Suwon-si (KR); Seokho Kim, Suwon-si (KR); Dongchan Lim, Suwon-si (KR)

(21) Appl. No.: 19/376,593

(22) Filed: Oct. 31, 2025

(30) Foreign Application Priority Data
Nov. 4, 2024 (KR) 10-2024-0154394

(51) Int. Cl. H01L 23/31; H01L 21/56; H01L 23/00; H01L 23/29; H01L 23/48; H01L 25/065

(52) U.S. Cl. CPC H10W 74/121; H10W 74/014; H10W 74/47; H10W 90/00; H10W 20/20; H10W 90/26; H10W 90/297; H10W 90/792

(57) ABSTRACT

A semiconductor package includes a first semiconductor chip, second semiconductor chips stacked on the first semiconductor chip, a first bonding layer structure between the second semiconductor chips and including a first bonding pad structure, and a filling pattern contacting at least a portion of each of the second semiconductor chips and including silicon oxide or polymer. A sidewall of the filling pattern is aligned with a sidewall of the first semiconductor chip in the vertical direction. The first bonding layer structure includes first and second bonding layers contacting each other. The first bonding pad structure includes first and second bonding pads in the first and second bonding layers, respectively, and contacting each other. The first bonding layer contacts an upper surface of a lower one of the second semiconductor chips. The second bonding layer contacts a lower surface of an upper one of the second semiconductor chips.

### CROSS-REFERENCE TO RELATED APPLICATION

This application claims priority under 35 U.S.C. § 119 to Korean Patent Application No. 10-2024-0154394, filed on Nov. 4, 2024, in the Korean Intellectual Property Office (KIPO), the contents of which are herein incorporated by reference in their entirety.

### BACKGROUND

In some examples, a high bandwidth memory (HBM) package may include a plurality of memory chips stacked on a logic chip in a vertical direction, and the memory chips may be bonded with each other by a bonding layer. If the bonding state between the memory chips is good, the HBM package may have enhanced performance, and thus a method of enhancing the bonding state between the memory chips may be desired.

### SUMMARY

Implementations according to present disclosure provides a semiconductor package having enhanced electrical characteristics.

An aspect of the present disclosure provides a semiconductor package. The semiconductor package may include a first semiconductor chip, second semiconductor chips stacked in a vertical direction on the first semiconductor chip, a first bonding layer structure between the second semiconductor chips and including a first bonding pad structure, and a filling pattern contacting at least a portion of each of the second semiconductor chips and including silicon oxide or polymer. A sidewall of the filling pattern may be aligned with a sidewall of the first semiconductor chip in the vertical direction. The first bonding layer structure may include a first bonding layer and a second bonding layer stacked in the vertical direction. The first and second bonding layers may contact each other. The first bonding pad structure may include a first bonding pad and a second bonding pad in the first bonding layer and the second bonding layer, respectively. The first and second bonding pads may contact each other. The first bonding layer may contact an upper surface of a lower one of the second semiconductor chips. The second bonding layer may contact a lower surface of an upper one of the second semiconductor chips.

Another aspect of the present disclosure provides a semiconductor package. The semiconductor package may include a first semiconductor chip, a bonding layer structure, a second semiconductor chip and a filling pattern. The bonding layer structure may be disposed on the first semiconductor chip and may include a bonding pad structure. The second semiconductor chip may be disposed on the bonding layer structure. The second semiconductor chip may include a substrate having first and second surfaces opposite to each other in a vertical direction, an insulating interlayer on the first surface of the substrate and contacting an upper surface of the bonding layer structure, a protective pattern structure on the second surface of the substrate, and a through electrode structure extending through the substrate, the insulating interlayer and the protective pattern structure and contacting the bonding pad structure. The filling pattern may be disposed on the bonding layer structure and may contact a sidewall of the substrate, a sidewall of the insulating interlayer and a lower surface of the protective pattern structure. The filling pattern may include silicon oxide or polymer.

Another aspect of the present disclosure provides a semiconductor package. The semiconductor package may include a buffer die, middle core dies stacked on the buffer die in a vertical direction, a first bonding layer structure between the buffer die and a lowermost one of the middle core dies and including a first bonding pad structure, a second bonding layer structure between the middle core dies and including a second bonding pad structure, a third bonding layer structure on an uppermost one of the middle core dies and including a third bonding pad structure, a top core die on the third bonding layer structure, and a filling pattern contacting a sidewall of a portion of each of the middle core dies, a sidewall of the filling pattern being aligned with a sidewall of the buffer die in the vertical direction and including silicon oxide or polymer.

In some implementations, the semiconductor may include the semiconductor chips stacked in the vertical direction, and the semiconductor chips may be bonded with each other through the bonding layer structure including the bonding pad structure. The bonding layer structure may include the bonding layers stacked in the vertical direction, and no void may exist between the bonding layers. Thus, the semiconductor package including the semiconductor chips bonded to each other through the bonding layer structure may have enhanced electrical characteristics.

### BRIEF DESCRIPTION OF THE DRAWINGS

FIG. 1 is a cross-sectional view illustrating an example of a semiconductor package.

FIGS. 2 to 17 are plan views and cross-sectional views illustrating an example of a method of manufacturing a semiconductor package.

FIGS. 18 to 20 are cross-sectional views illustrating an example of a method of manufacturing a semiconductor package.

FIGS. 21 to 26 are a plan view and cross-sectional views illustrating an example of a method of manufacturing a semiconductor package.

FIGS. 27 to 31 are cross-sectional views illustrating an example of a method of manufacturing a semiconductor package.

FIG. 32 is a cross-sectional view illustrating an example of a semiconductor package.

FIG. 33 is a cross-sectional view illustrating an example of an electronic device.

### DETAILED DESCRIPTION

Hereinafter, implementations of the present disclosure will be explained in detail with reference to the accompanying drawings.

Hereinafter, two directions crossing each other among horizontal directions that are substantially parallel to an upper surface of a wafer or a substrate may be referred to as first and second directions, respectively, and a vertical direction substantially perpendicular to the upper surface of the wafer or the substrate may be referred to as a third direction D3. In an example implementation, the first and second directions D1 and D2 may be substantially perpendicular to each other.

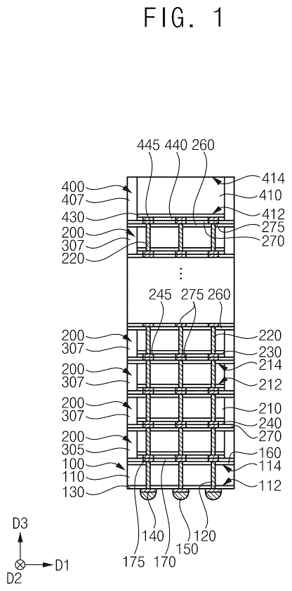

FIG. 1 is a cross-sectional view illustrating an example of a semiconductor package.

Referring to FIG. 1, the semiconductor package may include a first semiconductor chip 100, a plurality of second semiconductor chips 200 and a third semiconductor chip 400 stacked in the third direction D3.

The semiconductor package may further include first to third bonding layer structures, first to third filling patterns 305, 307 and 407, a conductive pad 140 and a first conductive connection member 150.

In some implementations, the semiconductor package may be a high bandwidth memory (HBM) package.

In some implementations, the first semiconductor chip 100 may be a buffer die, and may include a logic device, e.g., a controller. Each of the second and third semiconductor chips 200 and 400 may be a core die, and may include a volatile memory device, e.g., a DRAM device, an SRAM device, etc., or a non-volatile memory device, e.g., a flash memory device, an EEPROM device, etc. Each of the second semiconductor chips 200 may also be referred to as a middle core die, and the third semiconductor chip 400 may also be referred to as a top core die.

Additionally, the first semiconductor chip 100 may also be referred to as a logic chip or logic die, and each of the second and third semiconductor chips 200 and 400 may also be referred to as a memory chip or a memory die.

The first semiconductor chip 100 may include a first substrate 110 having first and second surfaces 112 and 114 opposite to each other in the third direction D3, a first insulating interlayer and a second insulating interlayer 130 sequentially stacked in the third direction D3 on the first surface 112 of the first substrate 110, a first protective pattern structure 160 on the second surface 114 of the first substrate 110, and a first through electrode structure 120 extending in the third direction D3 through the first substrate 110, the first insulating interlayer, the second insulating interlayer 130 and the first protective pattern structure 160.

The first substrate 110 may include a semiconductor material, e.g., silicon, germanium, silicon-germanium, or a III-V group compound semiconductor, e.g., GaP, GaAs, GaSb, etc. In some implementations, the first substrate 110 may be a silicon-on-insulator (SOI) substrate or a germanium-on-insulator (GOI) substrate.

A circuit device, e.g., a logic device may be disposed on the first surface 112 of the first substrate 110. The circuit device may include circuit patterns, which may be covered by the first insulating interlayer.

The second insulating interlayer 130 may include a first wiring structure therein. The first wiring structure may include, e.g., wirings, vias, contact plugs, etc.

The first insulating interlayer and the second insulating interlayer 130 may include, e.g., silicon oxide or a low-k dielectric material, e.g., an oxide doped with carbon or fluorine. The wirings, the vias, the contact plugs, etc., may include a conductive material, e.g., a metal, a metal nitride, a metal silicide, etc.

A plurality of first through electrode structures 120 may be spaced apart from each other in the horizontal direction. In some implementations, the first through electrode structure 120 may include a first through electrode extending in the vertical direction, a first barrier pattern covering a sidewall of the first through electrode, and a first insulation pattern covering an outer sidewall of the first barrier pattern. However, in some cases, the first insulation pattern may not cover an upper portion of the outer sidewall of the first barrier pattern.

The first through electrode structure 120 may be electrically connected to the circuit device in the first insulating interlayer and/or the first wiring structure in the second insulating interlayer 130.

The first through electrode may include a metal, e.g., copper, aluminum, etc., the first barrier pattern may include a metal nitride, e.g., titanium nitride, tantalum nitride, etc., and the first insulation pattern may include an oxide, e.g., silicon oxide or an insulating nitride, e.g., silicon nitride.

The first protective pattern structure 160 may be disposed on the second surface 114 of the first substrate 110, and may surround an upper portion of the first through electrode structure 120. In some implementations, the first protective pattern structure 160 may contact an outer sidewall of an upper portion of the first barrier pattern of the first through electrode structure 120.

In some implementations, the first protective pattern structure 160 may include a first protective pattern and a second protective pattern sequentially stacked in the third direction D3 on the second surface 114 of the first substrate 110. A portion of the first protective pattern adjacent to the first through electrode structure 120 may protrude upwardly in the third direction D3, and an upper surface of the portion of the first protective pattern may be substantially coplanar with an upper surface of the first through electrode structure 120. An outer sidewall of the portion of the first protective pattern may be covered by the second protective pattern.

The first protective pattern may include an oxide, e.g., silicon oxide, and the second protective pattern may include an insulating nitride, e.g., silicon nitride.

In some implementations, sidewalls of the first substrate 110, the first insulating interlayer, the second insulating interlayer 130 and the first protective pattern structure 160 may be aligned with each other in the third direction D3.

The conductive pad 140 may be disposed on a lower surface of the second insulating interlayer 130, and may contact a lower surface of the first wiring structure to be electrically connected thereto. In some implementations, a plurality of conductive pads 140 may be spaced apart from each other in the horizontal direction.

In some implementations, the conductive pad 140 may include a first seed pattern and first and second conductive patterns sequentially stacked downwardly in the third direction D3 from the lower surface of the second insulating interlayer 130. The first seed pattern may include, e.g., titanium, and the first and second conductive patterns may include, e.g., nickel and copper, respectively.

The first conductive connection member 150 may contact a lower surface of the conductive pad 140. The conductive connection member 150 may be, e.g., a conductive bump. The conductive connection member 150 may include a metal, e.g., tin, or solder that is a tin alloy such as tin/silver, tin/copper, tin/indium, tin/silver/copper, etc.

Each of the second semiconductor chips 200 may include a second substrate 210 having first and second surfaces 212 and 214 opposite to each other in the third direction D3, a third insulating interlayer and a fourth insulating interlayer 230 sequentially stacked in the third direction D3 on the first surface 212 of the second substrate 210, a second protective pattern structure 260 on the second surface 214 of the second substrate 210, and a second through electrode structure 220 extending in the third direction D3 through the second substrate 210, the third insulating interlayer, the fourth insulating interlayer 230 and the second protective pattern structure 260.

The second substrate 210 may include a semiconductor material, e.g., silicon, germanium, silicon-germanium, or a III-V group compound semiconductor, e.g., GaP, GaAs, GaSb, etc. In some implementations, the second substrate 210 may be a silicon-on-insulator (SOI) substrate or a germanium-on-insulator (GOI) substrate.

A circuit device, e.g., a volatile memory device such as a DRAM device, an SRAM device, etc., or a non-volatile memory device such as a flash memory device, an EEPROM device, etc., may be disposed on the first surface 212 of the second substrate 210. The circuit device may include circuit patterns, which may be covered by the third insulating interlayer.

The fourth insulating interlayer 230 may include a second wiring structure therein. The second wiring structure may include, e.g., wirings, vias, contact plugs, etc.

The third insulating interlayer and the fourth insulating interlayer 230 may include, e.g., silicon oxide or a low-k dielectric material, e.g., an oxide doped with carbon or fluorine. The wirings, the vias, the contact plugs, etc., may include a conductive material, e.g., a metal, a metal nitride, a metal silicide, etc.

A plurality of second through electrode structures 220 may be spaced apart from each other in the horizontal direction. In some implementations, the second through electrode structure 220 may include a second through electrode extending in the third direction D3, a second barrier pattern covering a sidewall of the second through electrode, and a second insulation pattern covering an outer sidewall of the second barrier pattern. However, in some implementations, the second insulation pattern may not cover an upper portion of the outer sidewall of the second barrier pattern.

The second through electrode structure 220 may be electrically connected to the circuit device in the third insulating interlayer and/or the second wiring structure in the fourth insulating interlayer 230.

The second through electrode may include a metal, e.g., copper, aluminum, etc., the second barrier pattern may include a metal nitride, e.g., titanium nitride, tantalum nitride, etc., and the second insulation pattern may include an oxide, e.g., silicon oxide or an insulating nitride, e.g., silicon nitride.

The second protective pattern structure 260 may be disposed on the second surface 214 of the second substrate 210, and may surround an upper portion of the second through electrode structure 220. In some implementations, the second protective pattern structure 260 may contact an outer sidewall of an upper portion of the second barrier pattern of the second through electrode structure 220.

In some implementations, the second protective pattern structure 260 may include a fourth protective pattern and a fifth protective pattern sequentially stacked in the third direction D3 on the second surface 214 of the second substrate 210. A portion of the fourth protective pattern adjacent to the second through electrode structure 220 may protrude upwardly in the third direction D3, and an upper surface of the portion of the fourth protective pattern may be substantially coplanar with an upper surface of the second through electrode structure 220. An outer sidewall of the portion of the fourth protective pattern may be covered by the fifth protective pattern.

The fourth protective pattern may include an oxide, e.g., silicon oxide, and the fifth protective pattern may include an insulating nitride, e.g., silicon nitride.

In some implementations, sidewalls of the second substrate 210, the third insulating interlayer and the fourth insulating interlayer 230 may be aligned with each other in the third direction D3, while a sidewall of the second protective pattern structure 260 may not be aligned with the sidewalls of the second substrate 210, the third insulating interlayer and the fourth insulating interlayer 230 in the third direction D3 but may be aligned with a sidewall of the first semiconductor chip 100.

A planar area of the first semiconductor chip 100 may be greater than planar areas of the second substrate 210, the third insulating interlayer and the fourth insulating interlayer 230 included in the second semiconductor chip 200, and may be substantially equal to a planar area of the second protective pattern structure 260 of the second semiconductor chip 200. Thus, widths in the first and second directions D1 and D2, respectively, of the first semiconductor chip 100 may be greater than widths in the first and second directions D1 and D2, respectively, of each of the second substrate 210, the third insulating interlayer and the fourth insulating interlayer 230 of the second semiconductor chip 200.

The first bonding layer structure may be interposed between the first and second semiconductor chips 100 and 200, and may include a first bonding layer 170 and a second bonding layer 240 stacked in the third direction D3.

The first bonding layer 170 may include a first bonding pad 175 therein. In some implementations, a sidewall of the first bonding layer 170 may be aligned with the sidewall of the first semiconductor chip 100 in the third direction D3. In some implementations, a plurality of first bonding pads 175 may be spaced apart from each other in the horizontal direction, and the first bonding pads 175 may contact upper surfaces of the first through electrode structures 120, respectively.

The second bonding layer 240 may include a second bonding pad 245 therein. In some implementations, a sidewall of the second bonding layer 240 may be aligned with the sidewalls of the second substrate 210, the third insulating interlayer and the fourth insulating interlayer 230 of the second semiconductor chip 200 in the third direction D3, and may not be aligned with a sidewall of the first bonding layer 170 in the third direction D3.

In some implementations, a plurality of second bonding pads 245 may be spaced apart from each other in the horizontal direction, and the second bonding pads 245 may contact lower surfaces of the second through electrode structures 220, respectively. The first and second bonding pads 175 and 245 may contact each other and be bonded with each other to form a first bonding pad structure.

Each of the first and second bonding layers 170 and 240 may include an insulating material, e.g., silicon carbonitride, silicon oxide, etc., and each of the first and second bonding pads 175 and 245 may include a metal, e.g., copper.

The first filling pattern 305 may be disposed on the first bonding layer 170, and may contact the sidewalls of the second substrate 210, the third insulating interlayer and the fourth insulating interlayer 230 included in a first one of the second semiconductor chips 200 that is disposed at a lowermost level among the second semiconductor chips 200, and the sidewall of the second bonding layer 240 under the lowermost one of the second semiconductor chips 200. The first filling pattern 305 may also contact an upper surface of an edge portion of the first bonding layer 170 and a lower surface of an edge portion of the second protective pattern structure 260 included in a second one of the second semiconductor chips 200 that is disposed at a second level from below among the second semiconductor chips 200.

In some implementations, a sidewall of the first filling pattern 305 may be aligned with a sidewall of the first bonding layer 170 and a sidewall of the second protective pattern structure 260 included in the first one of the second semiconductor chips 200 in the third direction D3.

The second filling pattern 307 may be disposed on a third bonding layer 270, and may contact the sidewalls of the second substrate 210, the third insulating interlayer and the fourth insulating interlayer 230 included in third ones of the second semiconductor chips 200 that are disposed at a plurality of levels except for the lowermost level among the second semiconductor chips 200, and the sidewalls of the second bonding layers 240 under the third ones of the second semiconductor chips 200. The second filling pattern 307 may also contact an upper surface of an edge portion of the third bonding layer 270 and a lower surface of an edge portion of the second protective pattern structure 260 included in each of the third ones of the second semiconductor chips 200.

In some implementations, a sidewall of the second filling pattern 307 may be aligned with a sidewall of the third bonding layer 270 and the sidewall of the second protective pattern structure 260 in the third direction D3.

Each of the first and second filling patterns 305 and 307 may include a material different from, e.g., epoxy molding compound (EMC). For example, each of the first and second filling patterns 305 and 307 may include an inorganic insulating material, e.g., silicon oxide, silicon nitride, etc., or polymer. The polymer may include, e.g., benzocyclobutene (BCB), polyimide (PI), imide-phenol resin, etc.

The second bonding layer structure may be interposed between the second semiconductor chips 200, and may include the third bonding layer 270 and the second bonding layer 240 stacked in the third direction D3.

The third bonding layer 270 may include a third bonding pad 275 therein. In some implementations, the sidewall of the third bonding layer 270 may be aligned with the sidewall of the second protective pattern structure 260 in the third direction D3. In some implementations, a plurality of third bonding pads 275 may be spaced apart from each other in the horizontal direction, and the third bonding pads 275 may contact the upper surfaces of the second through electrode structures 220, respectively.

The second and third bonding pads 245 and 275 may contact each other and be bonded to each other, and may collectively form a second bonding pad structure.

The third bonding layer 270 may include an insulating material, e.g., silicon carbonitride, silicon oxide, etc., and the third bonding pad 275 may include a metal, e.g., copper.

The third semiconductor chip 400 may include a third substrate 410 having first and second surfaces 412 and 414 opposite to each other in the third direction D3, a fifth insulating interlayer and a sixth insulating interlayer 430 sequentially stacked in the third direction D3 on the first surface 412 of the third substrate 410.

A circuit device, e.g., a volatile memory device or a non-volatile memory device may be disposed on the first surface 412 of the third substrate 410. The circuit device may include circuit patterns, which may be covered by the fifth insulating interlayer. The sixth insulating interlayer 430 may include a third wiring structure therein.

Alternatively, the third semiconductor chip 400 may not include the circuit device, the third wiring structure, the fifth insulating interlayer and the sixth insulating interlayer 430, and thus may be a dummy chip.

The third bonding layer structure may be interposed between an uppermost one of the second semiconductor chips 200 and the third semiconductor chip 400, and may include the third bonding layer 270 and a fourth bonding layer 440 stacked in the third direction D3.

The fourth bonding layer 440 may include a fourth bonding pad 445 therein. In some implementations, a sidewall of the fourth bonding layer 440 may be aligned with sidewalls of the third substrate 410, the fifth insulating interlayer and the sixth insulating interlayer 430 in the third direction D3. In some implementations, a plurality of fourth bonding pads 445 may be spaced apart from each other in the horizontal direction.

The third and fourth bonding pads 275 and 445 may contact each other and be bonded to each other, and may collectively form a third bonding pad structure.

The fourth bonding layer 440 may include an insulating material, e.g., silicon carbonitride, silicon oxide, etc., and the fourth bonding pad 445 may include a metal, e.g., copper.

The third filling pattern 407 may be disposed on the third bonding layer 270, and may contact the sidewalls of the third substrate 410, the fifth insulating interlayer and the sixth insulating interlayer 430 of the third semiconductor chip 400 and the sidewall of the fourth bonding layer 440 under the third semiconductor chip 400. The third filling pattern 407 may also contact the upper surface of the edge portion of the third bonding layer 270.

In some implementations, a sidewall of the third filling pattern 407 may be aligned with the sidewall of the third bonding layer 270 in the third direction D3.

The third filling pattern 407 may include an inorganic insulating material, e.g., silicon oxide, silicon nitride, etc., or polymer.

As illustrated below, during the manufacturing of the semiconductor package, the second semiconductor chips 200 stacked in the third direction D3 may be well bonded to each other through the second and third bonding layers 240 and 270 and the second and third bonding pads 245 and 275, and no void may be generated in the second and third bonding layers 240 and 270. Thus, the semiconductor package may have enhanced electrical characteristics.

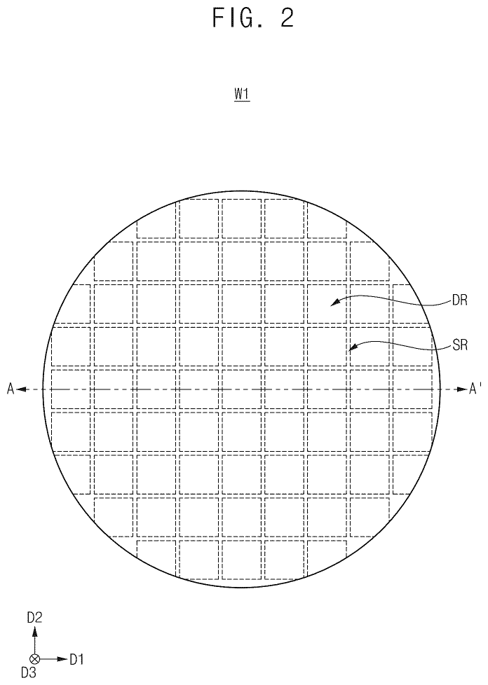

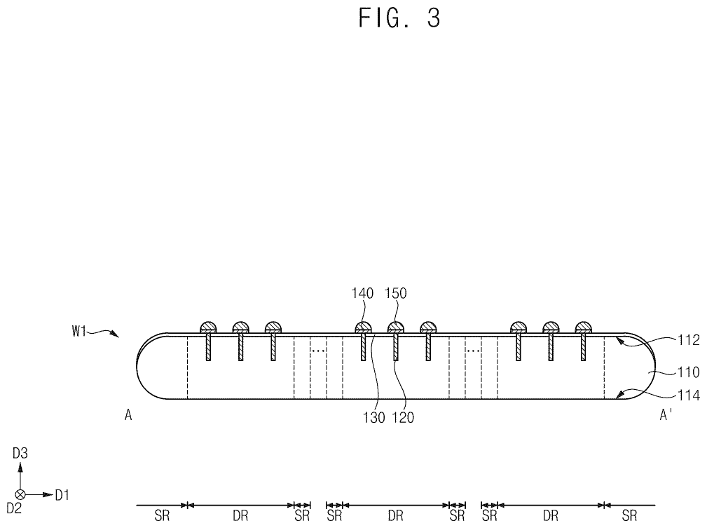

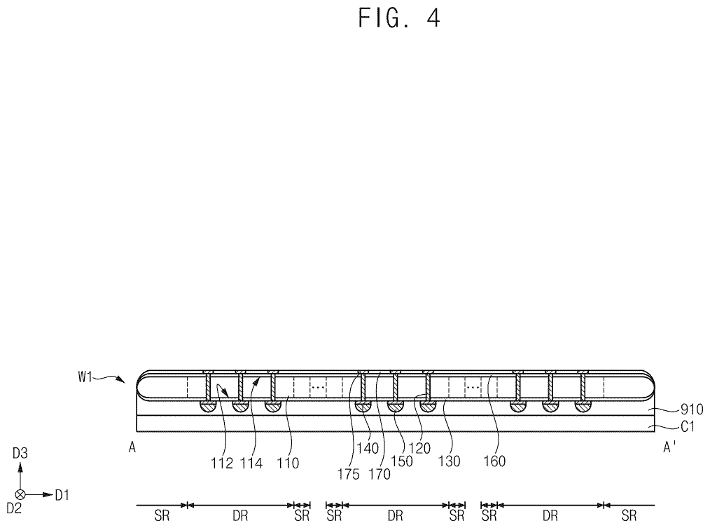

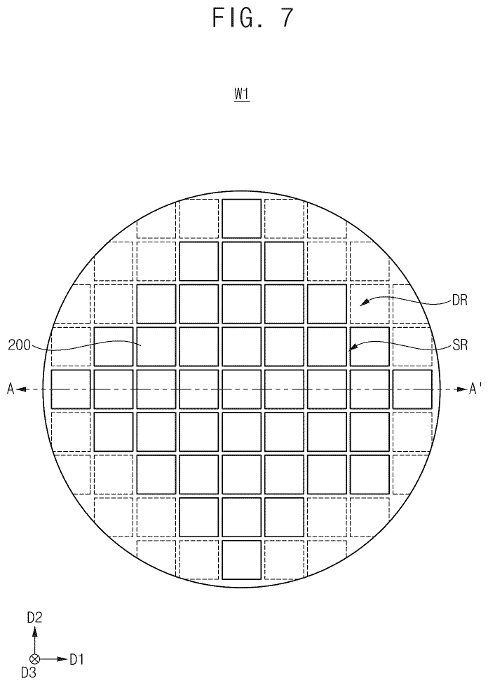

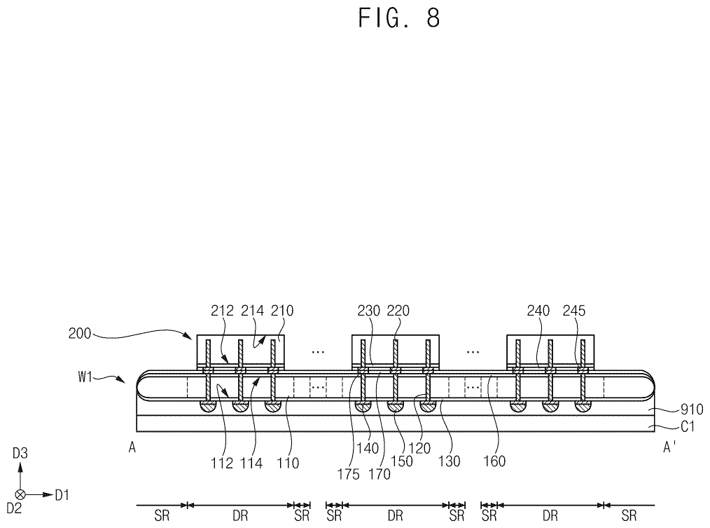

FIGS. 2 to 17 are plan views and cross-sectional views illustrating a method of manufacturing an example of a semiconductor package. Particularly, FIGS. 2 and 7 are the plan views, and FIGS. 3-6 and 8-17 are the cross-sectional views. FIGS. 3 and 4 are cross-sectional views taken along line A-A′ of FIG. 2, and FIGS. 8 to 17 are cross-sectional views taken along line A-A′ of FIG. 7.

Referring to FIGS. 2 and 3, a first wafer W1 may be provided.

In some implementations, the first wafer W1 may include a first substrate 110 having first and second surfaces 112 and 114 opposite to each other in the third direction D3. Additionally, the first wafer W1 may include a plurality of die regions DR and a scribe lane region SR surrounding each of the die regions DR. The first wafer W1 may be cut along the scribe lane region SR by a sawing process to be singulated into a plurality of first semiconductor chips.

In the die region DR, a circuit device may be disposed on the first surface 112 of the first substrate 110. The circuit device may include a logic device. The circuit device may include circuit patterns, and a first insulating interlayer may be formed on the first surface 112 of the first substrate 110 to cover the circuit patterns.

A second insulating interlayer 130 may be formed on the first insulating interlayer, and may include a first wiring structure therein.

In some implementations, a first through electrode structure 120 extending in the third direction D3 through an upper portion of the first substrate 110, that is, a portion of the first substrate 110 adjacent to the first surface 112 thereof, the first insulating interlayer and the second insulating interlayer 130 may be formed. In some implementations, a plurality of first through electrode structures 120 may be spaced apart from each other in the horizontal direction in each of the die regions DR of the first wafer W1.

In some implementations, the first through electrode structure 120 may include a first through electrode extending in the third direction D3, a first barrier pattern covering a sidewall and a lower surface of the first through electrode, and a first insulation pattern covering a sidewall and a lower surface of the first barrier pattern.

A conductive pad 140 may be formed on second insulating interlayer 130 to contact the first through electrode structure 120 to be electrically connected thereto.

In some implementations, the conductive pad 140 may be formed by following processes.

Particularly, a seed layer may be formed on the second insulating interlayer 130 and the first through electrode structure 120, a first photoresist pattern including a first opening partially exposing an upper surface of the seed layer may be formed on the seed layer, and an electroplating process or an electroless plating process may be performed to form first and second conductive patterns in the first opening.

The first photoresist pattern may be removed by, e.g., an ashing process and/or a stripping process to expose a portion of the seed layer, the exposed portion of the seed layer may be removed to form a seed pattern under the first conductive pattern.

Thus, the conductive pad 140 including the seed pattern and the first and second conductive patterns sequentially stacked in the third direction D3 may be formed.

A first conductive connection member 150 may be formed on the conductive pad 140. In some implementations, the first conductive connection member 150 may be formed by following processes.

Particularly, a second photoresist pattern including a second opening exposing an upper surface of the conductive pad 140 may be formed on the second insulating interlayer 130, and an electroplating process or an electroless plating process may be performed to form a preliminary first conductive connection member in the second opening. After removing the second photoresist pattern, a reflow process may be performed so that the preliminary first conductive connection member may be transformed into a first conductive connection member 150.

Referring to FIG. 4, a first temporary bonding layer 910 may be attached to a first carrier substrate C1, and the first temporary bonding layer 910 may be bonded with an upper surface of the second insulating interlayer 130 including the first wiring structure to cover the first conductive connection member 150 and the conductive pad 140 on the first wafer W1 so that the first carrier substrate C1 may be bonded with the first wafer W1.

The first temporary bonding layer 910 may include a material that may lose adhesion by irradiation of light, e.g., UV light or heat. In some implementations, the first temporary bonding layer 910 may include glue.

After flipping the first wafer W1, a portion of the first substrate 110 adjacent to the second surface 114 of the first substrate 110 may be removed by, e.g., a grinding process to expose an upper portion of the first through electrode structure 120.

In some implementations, an upper portion of the first insulation pattern of the first through electrode structure 120 may also be removed by the grinding process, and thus an upper surface and an upper outer sidewall of the first barrier pattern may be exposed.

A first protective layer structure may be formed on the second surface 114 of the first substrate 110 to cover the first through electrode structure 120, and a planarization process may be performed on the first protective layer structure until an upper surface of the first through electrode of the first through electrode structure 120 is exposed to form a first protective pattern structure 160.

In some implementations, the planarization process may include a chemical mechanical polishing (CMP) process and/or an etch back process.

In some implementations, the first protective layer structure may include first to third protective layers sequentially stacked in the third direction D3, and during the planarization process, the third protective layer may be removed and the second protective layer may partially remain. Thus, the first protective pattern structure 160 may include first and second protective patterns sequentially stacked in the third direction D3. An upper outer sidewall of a portion of the first protective pattern adjacent to the first through electrode structure 120 may be covered by the second protective pattern.

A first bonding layer 170 including a first bonding pad 175 therein may be formed on the first protective pattern structure 160 and the first through electrode structure 120.

In some implementations, a plurality of first bonding pads 175 may be spaced apart from each other in the horizontal direction, and some of the first bonding pads 175 may contact upper surfaces of the first through electrode structures 120, respectively.

In some implementations, the first bonding layer 170 may include an insulating material, e.g., silicon carbonitride, silicon oxide, etc., and the first bonding pad 175 may include a metal, e.g., copper.

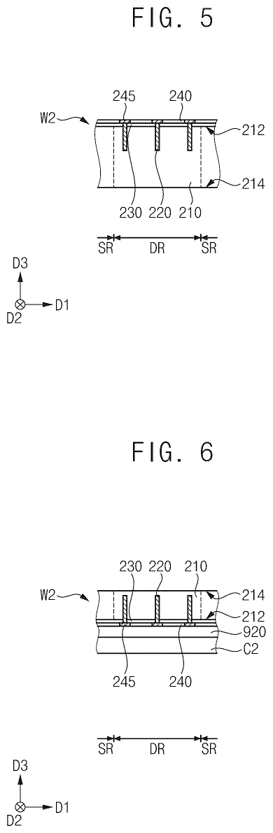

Referring to FIG. 5, a second wafer W2 may be provided.

In some implementations, the second wafer W2 may include a second substrate 210 having first and second surfaces 212 and 214 opposite to each other in the third direction D3. Additionally, the second wafer W2 may include a plurality of die regions DR and a scribe lane region SR surrounding each of the die regions DR. The second wafer W2 may be cut along the scribe lane region SR by a sawing process to be singulated into a plurality of second semiconductor chips.

In the die region DR, a circuit device may be formed on the first surface 212 of the second substrate 210. The circuit device may include a memory device. The circuit device may include circuit patterns, and a third insulating interlayer may be formed on the first surface 212 of the second substrate 210 to cover the circuit patterns.

A fourth insulating interlayer 230 may be formed on the third insulating interlayer, and may include a second wiring structure therein.

In some implementations, a second through electrode structure 220 extending in the third direction D3 through an upper portion of the second substrate 210, that is, a portion of the second substrate 210 adjacent to the first surface 212 thereof, the third insulating interlayer and the fourth insulating interlayer 230 may be formed. In some implementations, a plurality of second through electrode structures 220 may be spaced apart from each other in the horizontal direction in each of the die regions DR of the second wafer W2.

In some implementations, the second through electrode structure 220 may include a second through electrode extending in the third direction D3, a second barrier pattern covering a sidewall and a lower surface of the second through electrode, and a second insulation pattern covering a sidewall and a lower surface of the second barrier pattern.

A second bonding layer 240 including a second bonding pad 245 therein may be formed on the fourth insulating interlayer 230 including the second wiring structure and the second through electrode structure 220.

In some implementations, a plurality of second bonding pads 245 may be spaced apart from each other in the horizontal direction, and some of the second bonding pads 245 may contact upper surfaces of the second through electrode structures 220, respectively.

In some implementations, the second bonding layer 240 may include an insulating material, e.g., silicon carbonitride, silicon oxide, etc., and the second bonding pad 245 may include a metal, e.g., copper.

Referring to FIG. 6, a second temporary bonding layer 920 may be attached to a second carrier substrate C2, and the second temporary bonding layer 920 may be bonded with an upper surface of the second bonding layer 240 including the second bonding pad 245 on the second wafer W2 so that the second carrier substrate C2 may be bonded with the second wafer W2.

The second temporary bonding layer 920 may include a material that may lose adhesion by irradiation of light, e.g., UV light or heat. In some implementations, the second temporary bonding layer 920 may include glue.

After flipping the second wafer W2, a portion of the second substrate 210 adjacent to the second surface 214 of the second substrate 210 may be removed by, e.g., a grinding process and/or a CMP process.

Referring to FIGS. 7 and 8, after flipping the second wafer W2, the second wafer W2 may be attached to an upper surface of a release tape on a ring frame.

The release tape may contact the second surface 214 of the second substrate 210 included in the second wafer W2.

The second temporary bonding layer 920 attached to the second carrier substrate C2 may be separated from the second bonding layer 240 so that the second carrier substrate C2 may be separated from the second wafer W2.

The second wafer W2 may be cut along the scribe lane region SR to be singulated into a plurality of second semiconductor chips 200.

Each of the second semiconductor chips 200 may be separated from the release tape, the second bonding layer 240 of each of the second semiconductor chips 200 may contact an upper surface of the first bonding layer 170 of the first wafer W1 so that each of the second semiconductor chips 200 may be mounted onto the first wafer W1.

The second semiconductor chips 200 may be arranged on the first wafer W1 such that the second semiconductor chips 200 may be disposed on central ones, respectively, of the die regions DRs except for edge ones of the die region DRs, and the second bonding pad 245 of each of the second semiconductor chips 200 may contact an upper surface of the first bonding pad 175 of the first semiconductor chip.

Thus, the first and second bonding layers 170 and 240 may be bonded to each other to form a first bonding layer structure, and the first and second bonding pads 175 and 245 may be bonded to each other to form a first bonding pad structure. That is, each of the second semiconductor chips 200 may be bonded to the first wafer W1 by a hybrid copper bonding (HCB) process.

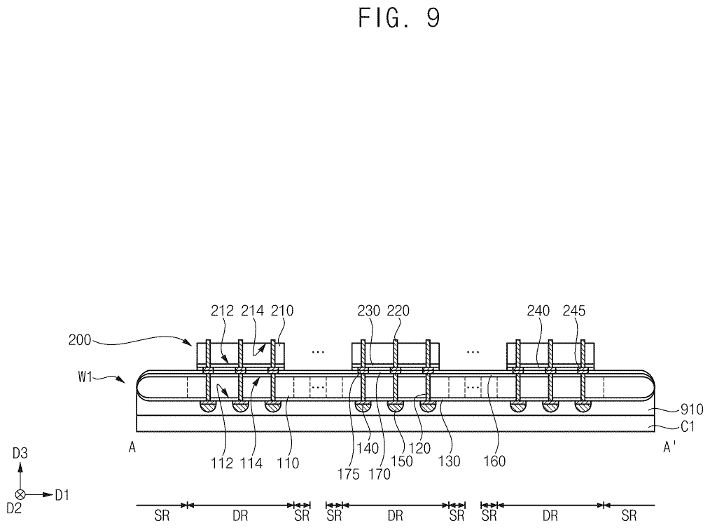

Referring to FIG. 9, a portion of the second substrate 210 adjacent to the second surface 214 of the second substrate 210 may be removed by, e.g., a grinding process and/or a CMP process to expose an upper portion of the second through electrode structure 220.

In some implementations, an upper portion of the second insulation pattern included in the second through electrode structure 220 may also be removed during the grinding process and/or a CMP process, and thus an upper surface and an upper outer sidewall of the second barrier pattern may be exposed.

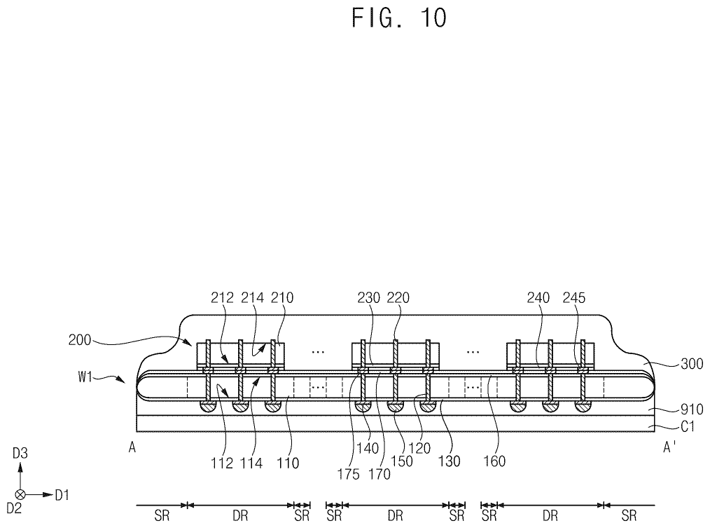

Referring to FIG. 10, a filling layer 300 may be formed on the first bonding layer 170 to cover the second semiconductor chip 200 and the second bonding layer 240.

The second semiconductor chips 200 may be disposed on a central portion of the first wafer W1 but may not be disposed on an edge portion of the first wafer W1, and thus an upper surface of a portion of the filling layer 300 on the edge portion of the first wafer W1 may be higher than an upper surface of a portion of the filling layer 300 on the central portion of the first wafer W1.

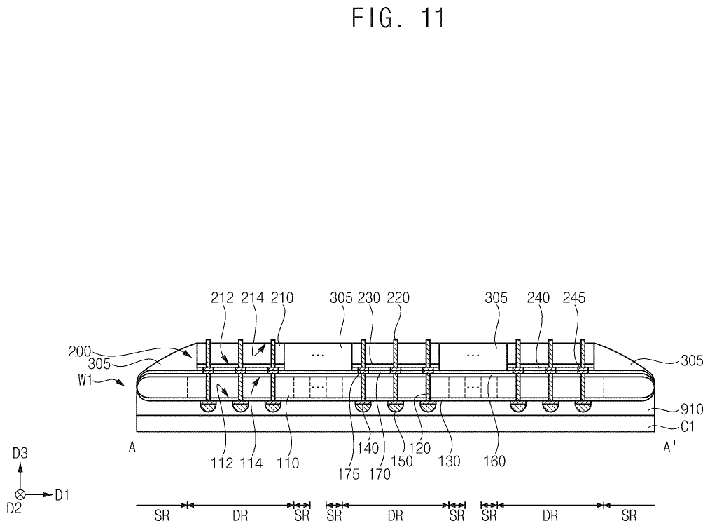

Referring to FIG. 11, a grinding process and/or a CMP process may be performed on the filling layer 300 until the second surface 214 of the second substrate 210 included in the second semiconductor chip 200 is exposed.

Thus, a first filling pattern 305 may remain between the second semiconductor chips 200, and an upper portion of the second through electrode structure 220 protruding over the second surface 214 of the second substrate 210 in each of the second semiconductor chips 200 may be exposed. In some implementations, an upper surface of the first filling pattern 305 may be substantially coplanar with the second surface 214 of the second substrate 210.

Unlike the illustration of FIG. 9, in some implementations, before performing the grinding process and/or the CMP process on the portion of the second substrate 210 adjacent to the second surface 214 of the second substrate 210, after the processes illustrated with reference to FIG. 10 are performed to form the filling layer 300 on the first bonding layer 170 to cover the second semiconductor chip 200 and the second bonding layer 240, the grinding process and/or the CMP process illustrated with reference to FIG. 11 may be performed on the filling layer 300.

During the grinding process and/or the CMP process, a portion of the second substrate 210 adjacent to the second surface 214 of the second substrate 210 in each of the second semiconductor chips 200 may also be removed, and an upper portion of the second through electrode structure 220 may be exposed.

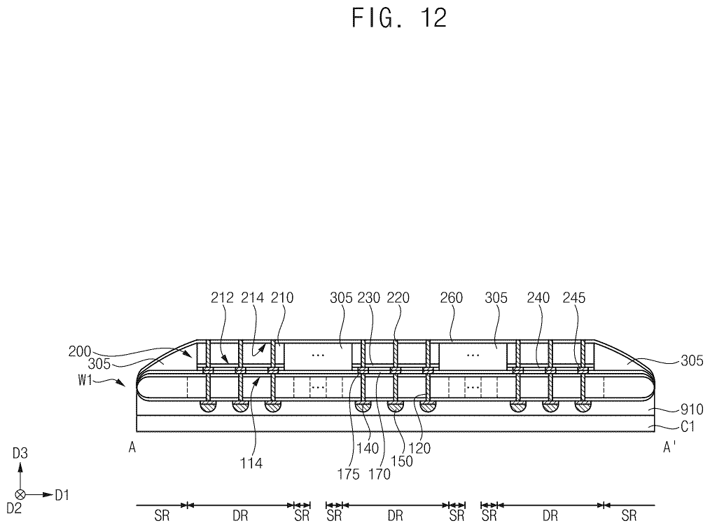

Referring to FIG. 12, a second protective layer structure may be formed on the second surface 214 of the second substrate 210 in the second semiconductor chip 200 and the first filling pattern 305, and a planarization process, e.g., a CMP process and/or an etch back process may be performed on the second protective layer structure until the second through electrode of the second through electrode structure 220 is exposed to form a second protective pattern structure 260.

In some implementations, the second protective layer structure may include fourth to sixth protective layers sequentially stacked in the third direction D3, and during the planarization process, the sixth protective layer may be removed, and the fourth and fifth protective layers may partially remain. Thus, the second protective pattern structure 260 may include fourth and fifth protective patterns stacked in the third direction D3. An upper outer sidewall of a portion of the fourth protective pattern adjacent to the second through electrode structure 220 may be covered by the fifth protective pattern.

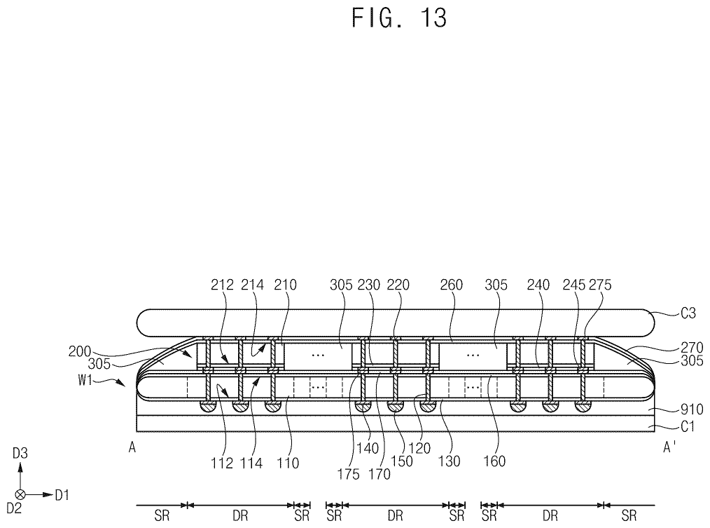

Referring to FIG. 13, a third bonding layer 270 may be formed on the second protective pattern structure 260, third bonding pads may be formed through the third bonding layer 270 to contact upper surfaces of the second through electrode structures 220, respectively, and a third carrier substrate C3 may be mounted on the third bonding layer 270 and the third bonding pads 275.

The third carrier substrate C3 may include a semiconductor material, e.g., silicon, germanium, silicon-germanium, or a III-V group compound semiconductor, e.g., GaP, GaAs, GaSb, etc. Alternatively, the third carrier substrate C3 may include an insulating material, e.g., glass.

In some implementations, a plurality of third bonding pads 275 may be spaced apart from each other in the horizontal direction, and may contact the upper surfaces of the second through electrode structures 220, respectively.

In some implementations, the third bonding layer 270 may include an insulating material, e.g., silicon carbonitride, silicon oxide, etc., and the third bonding pad 275 may include a metal, e.g., copper.

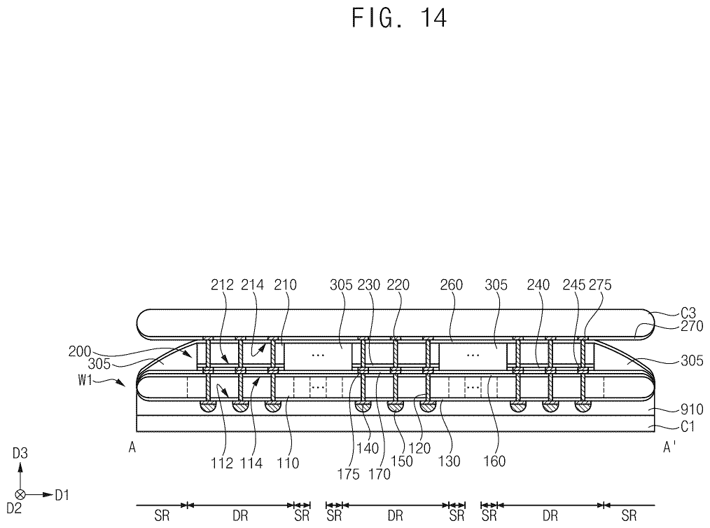

Referring to FIG. 14, unlike the illustration with reference to FIG. 13, the third bonding layer 270 including the third bonding pads 275 may be formed on a surface of the third carrier substrate C3, and the third bonding layer 270 may contact the upper surface of the second protective pattern structure 260 so that the third carrier substrate C3 may be stacked on the second semiconductor chips 200.

Hereinafter, only the case of FIG. 13 is illustrated.

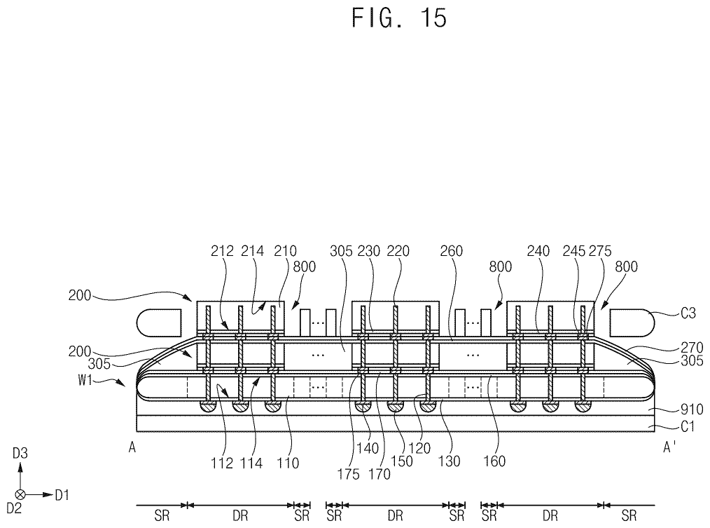

Referring to FIG. 15, the third carrier substrate C3 may be partially removed by an etching process to form a third opening 800 exposing an upper surface of the third bonding layer 270, and the second semiconductor chip 200 may be mounted into the third opening 800.

When the second semiconductor chip 200 is mounted, the second bonding layer 240 of the second semiconductor chip 200 may contact the upper surface of the third bonding layer 270.

In some implementations, the third opening 800 may be formed at a portion of the third carrier substrate C3 overlapping in the third direction D3 the second semiconductor chip 200 at the same level as the first filling pattern 305, and a plurality of third openings 800 may be spaced apart from each other in the horizontal direction.

The second bonding pad 245 in the second semiconductor chips 200 that may be disposed in each of the third openings 800 may contact an upper surface of the third bonding pad 275. Thus, the second and third bonding layers 240 and 270 may be bonded to each other to form a second bonding layer structure, and the second and third bonding pads 245 and 275 may be bonded to each other to form a second bonding pad structure. That is, a first one of the second semiconductor chips 200 disposed in the third opening 800 may be bonded to a second one of the second semiconductor chips 200 disposed under the first one by an HCB process.

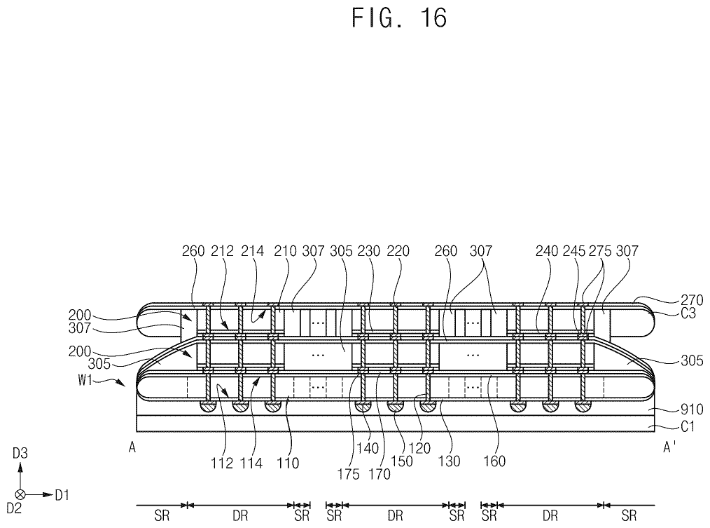

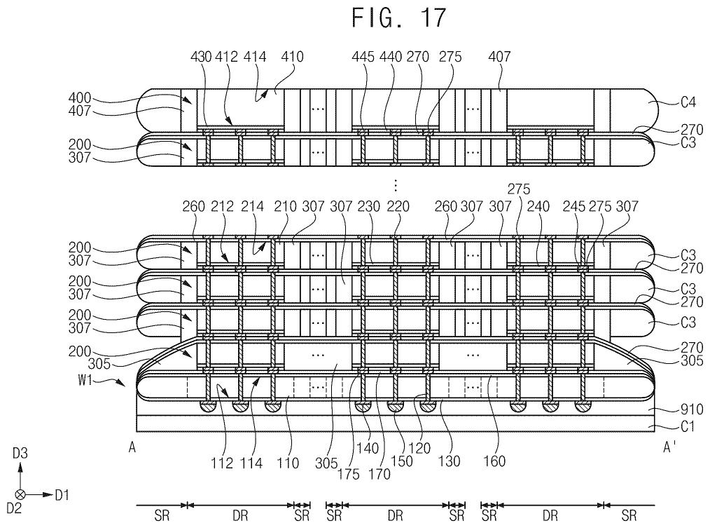

Referring to FIG. 16, processes substantially the same as or similar to those illustrated with reference to FIGS. 9 to 12 may be performed.

Thus, the portion of the second substrate 210 adjacent to the second surface 214 of the second substrate 210 may be removed by, e.g., a grinding process and/or a CMP process to expose the upper portion of the second through electrode structure 220, the filling layer 300 may be formed on the third bonding layer 270 to cover the second semiconductor chip 200, the second bonding layer 240 and the third carrier substrate C3, and a grinding process and/or a CMP process may be performed on the filling layer 300 until the second surface 214 of the second substrate 210 included in the second semiconductor chip 200 is exposed to form a second filling pattern 307 between the second semiconductor chips 200 and the third carrier substrate C3.

The second protective layer structure may be formed on the second surface 214 of the second substrate 210 in the second semiconductor chip 200, the second filling pattern 307 and the third carrier substrate C3 to cover the second through electrode structure 220, and a planarization process, e.g., a CMP process and/or an etch back process may be performed on the second protective layer structure until the second through electrode of the second through electrode structure 220 is exposed to form the second protective pattern structure 260.

The third bonding layer 270 may be formed on the second protective pattern structure 260, and the third bonding pads 275 may be formed through the third bonding layer 270 to contact the upper surfaces of the second through electrode structures 220, respectively.

Referring to FIG. 17, as illustrated with reference to FIG. 13, the third carrier substrate C3 may be mounted on the third bonding layer 270 and the third bonding pads 275, and processes substantially the same as or similar to those illustrated with reference to FIGS. 15 and 16 may be performed so that a plurality of third carrier substrates C3 and a plurality of second semiconductor chips 200 may be stacked in the third direction D3, and a fourth carrier substrate C4 and a third semiconductor chip 400 may be stacked in the third direction D3 on an uppermost one of the third carrier substrates C3 and uppermost ones of the second semiconductor chips 200.

The third semiconductor chip 400 may include a third substrate 410 having first and second surfaces 412 and 414 opposite to each other in the third direction D3. In some implementations, a thickness in the third direction D3 of the third semiconductor chip 400 may be greater than a thickness in the third direction D3 of the second semiconductor chip 200, and a thickness in the third direction D3 of the fourth carrier substrate C4 may also be greater than a thickness in the third direction D3 of the third substrate C3.

The third semiconductor chip 400 may not include a through electrode structure and a protective pattern structure covering an upper portion of the through electrode structure.

In some implementations, a circuit device may be disposed on the first surface 412 of the third substrate 410 included in the third semiconductor chip 400, and may include a memory device. The circuit device may include a plurality of circuit patterns, and a fifth insulating interlayer may be disposed on the first surface 412 of the third substrate 410 and cover the circuit patterns. A sixth insulating interlayer 430 may be disposed on a lower surface of the fifth insulating interlayer, and may include a third wiring structure.

Alternatively, the third semiconductor chip 400 may be a dummy chip. Thus, the third semiconductor chip 400 may not include the circuit device, the wiring structure, the fifth insulating interlayer and the sixth insulating interlayer 430.

A fourth bonding layer 440 including a fourth bonding pad 445 therein may be disposed on a lower surface of the sixth insulating interlayer 430, and may contact the third bonding layer 270. The third and fourth bonding layers 270 and 440 may be bonded to each other to form a third bonding layer structure, and the third and fourth bonding pads 275 and 445 may be bonded to each other to form a third bonding pad structure. That is, the third semiconductor chip 400 may be bonded to the second semiconductor chip 200 by an HCB process.

A third filling pattern 407 may be formed between the third semiconductor chips 400 and the fourth carrier substrate C4.

Referring to FIG. 1 again, the first wafer W1 may be cut along the scribe lane region SR by, e.g., a sawing process to be singulated into a plurality of first semiconductor chips 100.

During the sawing process, the first to third filling patterns 305, 307 and 407 may also be cut to be formed on each of the first semiconductor chips 100, and may cover sidewalls of the second and third semiconductor chips 200 and 400 and the second and fourth bonding layers 240 and 440.

The first temporary bonding layer 910 and the first carrier substrate C1 may be separated from each of the first semiconductor chips 100 to complete the manufacturing of the semiconductor package.

As illustrated above, the filling layer 300 may be formed on the first bonding layer 170 to cover the second semiconductor chips 200 and the second bonding layers 240, the upper portion of the filling layer 300 may be removed to form the first filling pattern 305, and the second protective pattern structure 260 may be formed on the second through electrode structure 220 and the first filling pattern 305. The third bonding layer 270 and the third carrier substrate C3 may be stacked on the second protective pattern structure 260, the third carrier substrate C3 may be partially removed to form the third openings 800 exposing the upper surface of the third bonding layer 270, and the second semiconductor chips 200 may be bonded in the third openings 800 through the second bonding layers 240.

The portion of the second substrate 210 adjacent to the second surface 214 of the second substrate 210 included in each of the second semiconductor chips 200 may be removed by the grinding process and/or the CMP process to expose the upper portion of the second through electrode structure 220, the filling layer 300 may be formed on the third bonding layer 270 to cover the second semiconductor chips 200, the second bonding layer 240 and the third carrier substrate C3, and the upper portion of the filling layer 300 may be removed to form the second filling pattern 307.

If the second semiconductor chips 200 are bonded onto the third bonding layer 270 through the second bonding layers 240 without using the third carrier substrate C3, a height of an upper surface of a portion of the filling layer 300 on an edge portion of the first wafer W1 on which the second semiconductor chips 200 are not disposed and a height of an upper surface of a portion of the filling layer 300 on a central portion of the first wafer W1 on which the second semiconductor chips 200 are disposed may be different from each other, and thus a height difference may occur. Thus, when upper portions of the second semiconductor chips 200 are removed by the grinding process and/or the CMP process, an amount of upper portions of the second through electrode structures 220 included in the second semiconductor chips 200 that may be exposed may not be uniform so that the grinding process and/or the CMP process may not be easily performed.

However, in some implementations, the second semiconductor chips 200 may be bonded through the second bonding layers 240 in the third openings 800, which may be formed by partially removing the third carrier substrate C3, and an edge portion of the third carrier substrate C3 may exist on the edge portion of the first wafer W1 on which the second semiconductor chips are not disposed, and thus, when the upper portions of the second semiconductor chips 200 are removed, the grinding process and/or the CMP process may be performed such that the upper portions of the second through electrode structures 220 included in the second semiconductor chips 200 may be exposed by a uniform amount.

Accordingly, the second protective pattern structure 260 covering the upper portions of the second through electrode structure 220 may be formed to have a uniform thickness, and when the second semiconductor chips 200 are repeatedly stacked in the third direction D3 through the second and third bonding layers 240 and 270, the third carrier substrate C3 may be used so that no void may be generated between the second and third bonding layers 240 and 270.

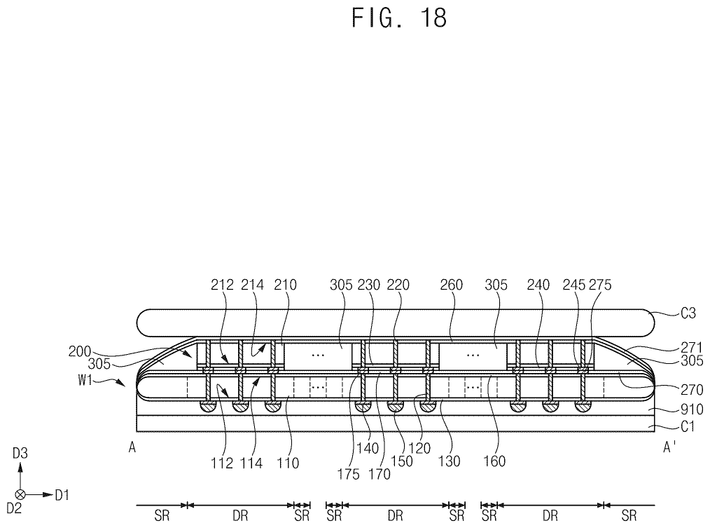

FIGS. 18 to 20 are cross-sectional views illustrating a method of manufacturing an example of a semiconductor package. This method may include processes substantially the same as or similar to those illustrated with reference to FIGS. 2 to 17 and FIG. 1, and thus repeated explanations thereof are omitted herein.

Referring to FIG. 18, processes substantially the same as or similar to those illustrated with reference to FIGS. 2 to 13 may be performed.

However, a fifth bonding layer 271, instead of the third bonding layer 270, may be formed on a surface of the third carrier substrate C3, and the fifth bonding layer may not include a bonding pad. The fifth bonding layer 271 may include an insulating material, e.g., silicon carbonitride, silicon oxide, etc.

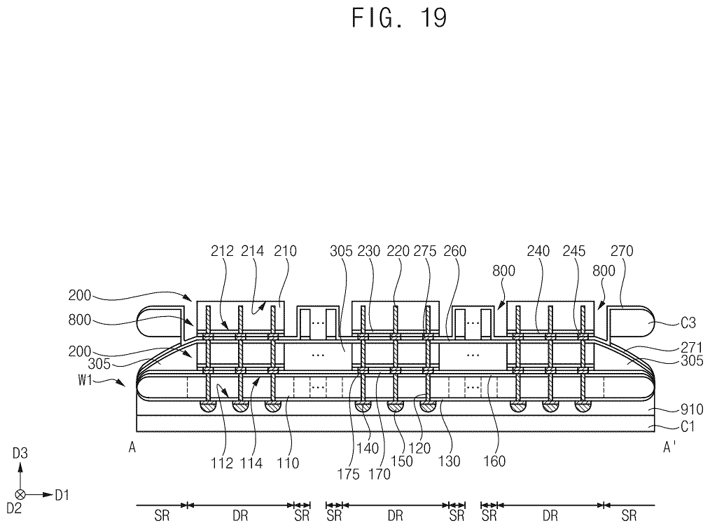

Referring to FIG. 19, processes substantially the same as or similar to those illustrated with reference to FIG. 15 may be performed.

However, the third opening 800 may be formed by partially removing the fifth bonding layer 271 as well as the third carrier substrate C3, and thus may expose the upper surfaces of the second protective pattern structure 260 and the second through electrode structure 220.

Additionally, before mounting the second semiconductor chip 200 in the third opening 800, the third bonding layer 270 including the bonding pads 275 may be formed on the second protective pattern structure 260, the second through electrode 220 and the third carrier substrate C3.

Each of the third bonding pads 275 may contact the upper surface of the second through electrode structure 220. The second bonding layer 240 in the second semiconductor chip 200 that may be mounted on the third bonding layer 270 may contact the upper surface of the third bonding layer 270, and the second bonding pads 245 in the second bonding layer 240 may contact the upper surfaces of the third bonding pads 275, respectively, in the third bonding layer 270.

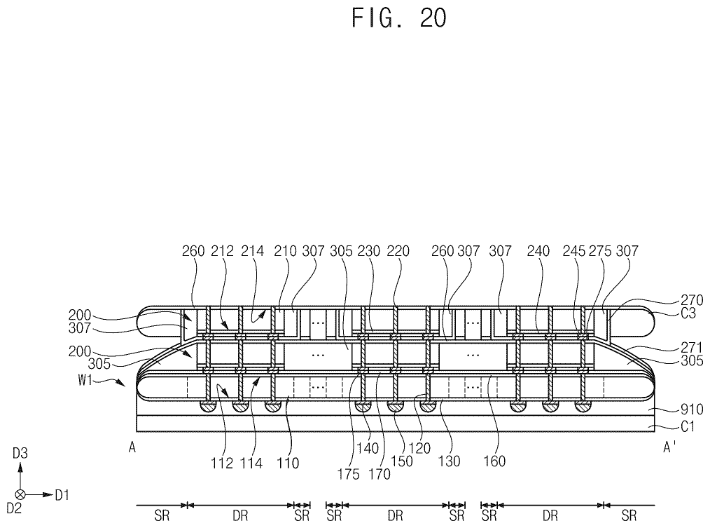

Referring to FIG. 20, processes substantially the same as or similar to those illustrated with reference to FIG. 16 may be performed.

Then, processes substantially the same as or similar to those illustrated with reference to FIG. 17 and FIG. 1 may be performed to complete the manufacturing of the semiconductor package.

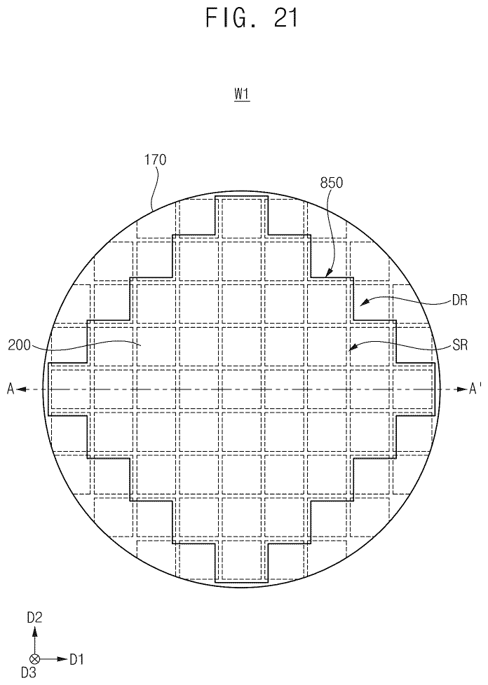

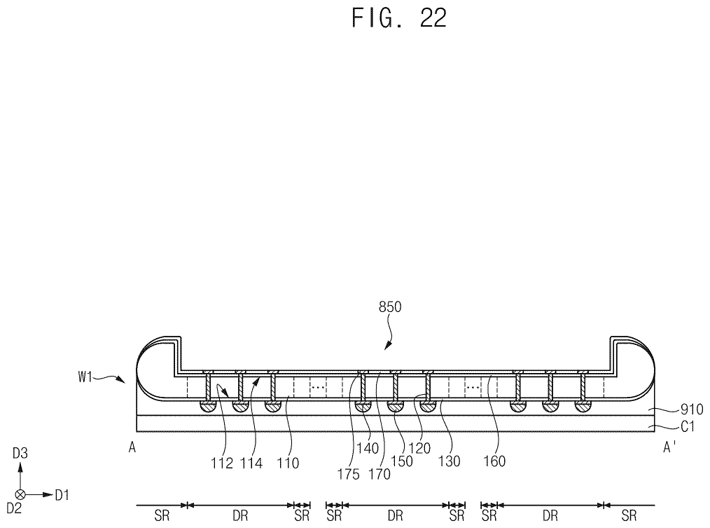

FIGS. 21 to 26 are a plan view and cross-sectional views illustrating a method of manufacturing an example of a semiconductor package. Particularly, FIG. 21 is the plan view, and FIGS. 22 to 26 are the cross-sectional views. This method may include processes substantially the same as or similar to those illustrated with reference to FIGS. 2 to 17 and FIG. 1, and thus repeated explanations thereof are omitted herein.

Referring to FIGS. 21 and 22, processes substantially the same as or similar to those illustrated with reference to FIGS. 2 to 4 may be performed.

However, after flipping the first wafer W1, a portion of the first substrate 110 adjacent to the second surface 114 of the first substrate 110 may be partially removed to form a first trench 850 exposing an upper surface of the first through electrode structure 120.

In some implementations, the first trench 850 may be formed by partially removing a central portion of the first wafer W1, which may correspond to the die regions DRs on which the second semiconductor chips 200 are disposed and a portion of the scribe lane region SR surrounding the die regions DRs.

After forming the first trench 850, the first protective pattern structure 160 may be formed on a sidewall of the first trench 850 and the upper surface of the first wafer W1, and the first bonding layer 170 including the first bonding pad 175 may be formed on the first protective pattern structure 160 and the first through electrode structure 120.

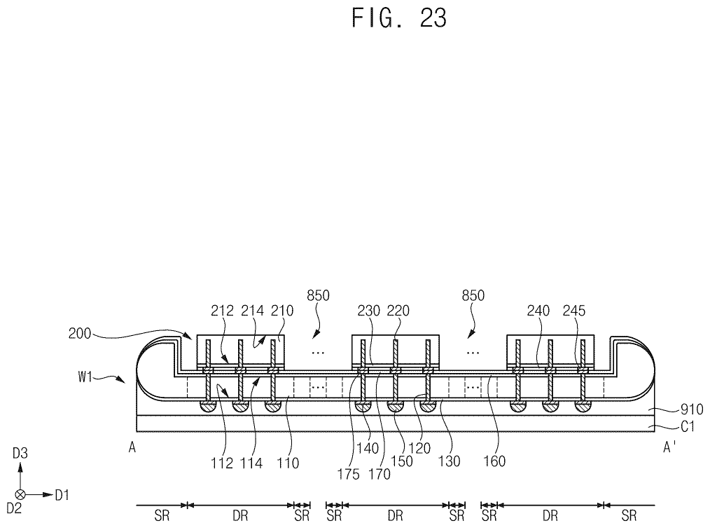

Referring to FIG. 23, processes substantially the same as or similar to those illustrated with respect to FIGS. 7 and 8 may be performed so that the second semiconductor chips 200 may be mounted onto the first bonding layer 170.

In some implementations, an upper surface of each of the second semiconductor chips 200 may be higher than an upper surface of an edge portion of the first wafer W1 on which the first trench 850 is not formed, that is, an uppermost surface of the first wafer W1, and an uppermost surface of the second through electrode structure 220 included in each of the second semiconductor chips 200 may be higher than the uppermost surface of the first wafer W1.

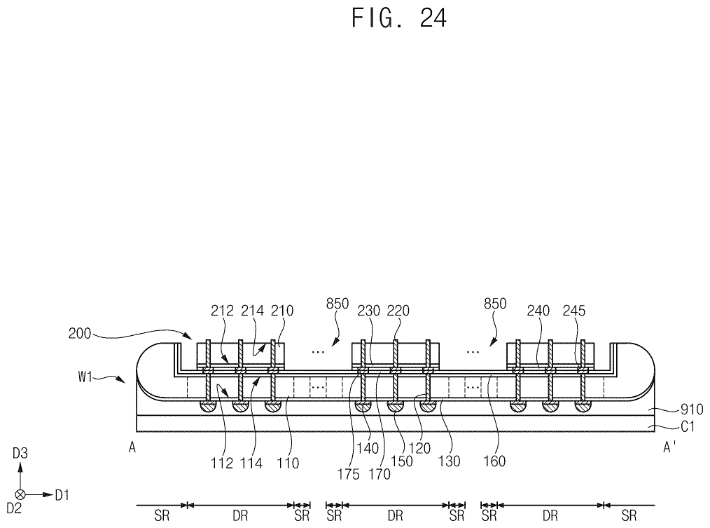

Referring to FIG. 24, for example, a grinding process and/or a CMP process may be performed to remove a portion of the second substrate 210 adjacent to the second surface 214 in the second semiconductor chip 200 may be removed to expose an upper portion of the second through electrode structure 220.

During the grinding process and/or a CMP process, portions of the first bonding layer 170 and the first protective pattern structure 160 on the edge portion of the first wafer W1 on which the first trench 850 is not formed may also be removed so that the upper surface of the edge portion of the first wafer W1, that is, the uppermost surface of the first wafer W1 may be exposed.

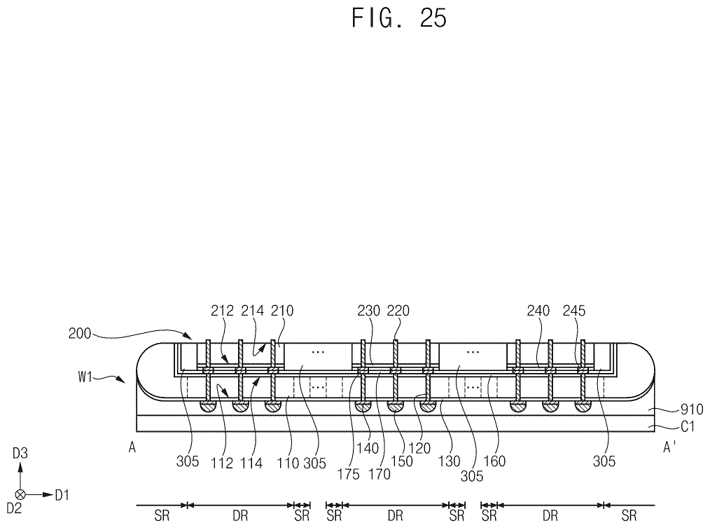

Referring to FIG. 25, processes substantially the same as or similar to those illustrated with respect to FIGS. 10 and 11 may be performed to form the first filling pattern 305.

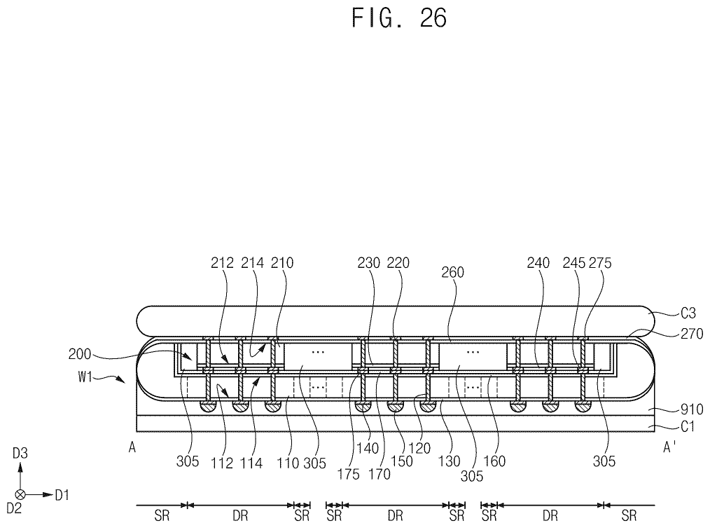

Referring to FIG. 26, processes substantially the same as or similar to those illustrated with respect to FIGS. 12 and 13 may be performed.

Thus, the second protective pattern structure 260 may be formed on the second surface 214 of the second substrate 210 in the second semiconductor chip 200, an upper surface of the first filling pattern 305 and the upper surface of the edge portion of the first wafer W1, the third bonding layer 270 may be formed on the second protective pattern structure 260, and the third bonding pads 275 may be formed through the third bonding layer 270 to contact upper surfaces of the second through electrode structures 220, respectively.

The third carrier substrate C3 may be mounted onto the third bonding layer 270 and the third bonding pads 275.

Processes substantially the same as or similar to those illustrated with respect to FIGS. 15 to 17 may be performed to complete the manufacturing of the semiconductor package.

As illustrated above, the upper portion of the first wafer W1 may be partially removed to form the first trench 850 exposing the upper portion of the first through electrode structure 120, the first protective pattern structure 160 and the first bonding layer 170 may be formed in the first trench 850, and the second semiconductor chips 200 may be bonded to the first bonding layer 170 through the second bonding layers 240.

The upper portion of each of the second semiconductor chips 200 may be removed to expose the upper portion of the second through electrode structure 220, the filling layer 300 may be formed on the first bonding layer 170 to cover the second semiconductor chips 200, the second bonding layers 240 and the first wafer W1, and the upper portion of the filling layer 300 may be removed to form the first filling pattern 305.

Thus, the first trench 850 may not be formed on the edge portion of the first wafer W1 on which the second semiconductor chips 200 are not disposed, and the upper surface of the edge portion of the first wafer W1 may have a height similar to a height of the upper surfaces of the second semiconductor chips 200 mounted on the first trench 850. Accordingly, the upper surface of the first filling pattern 305, which may be formed by removing the upper portion of the filling layer 300, the second surface 214 of the second substrate 210 in each of the second semiconductor chips 200 and the upper surface of the edge portion of the first wafer W1 may be substantially coplanar with each other, and the upper surface of the second protective pattern structure 260, which may be disposed on the upper surface of the first filling pattern 305, the second surface 214 of the second substrate 210 in each of the second semiconductor chips 200 and the upper surface of the edge portion of the first wafer W1 and cover the upper portion of the second through electrode structure 220 in each of the second semiconductor chips 200, may have a uniform height.

As a result, a lower surface of the third bonding layer 270 on the surface of the third carrier substrate C3 that may be stacked on the second protective pattern structure 260 may contact the second protective pattern structure 260 well, and no void may be generated between the third bonding layer 270 and the second protective pattern structure 260. Accordingly, when the second semiconductor chips 200 are repeatedly stacked using the third carrier substrate C3, lower and upper second semiconductor chips 200 may be well bonded to each other through the second and third bonding layers 240 and 270.

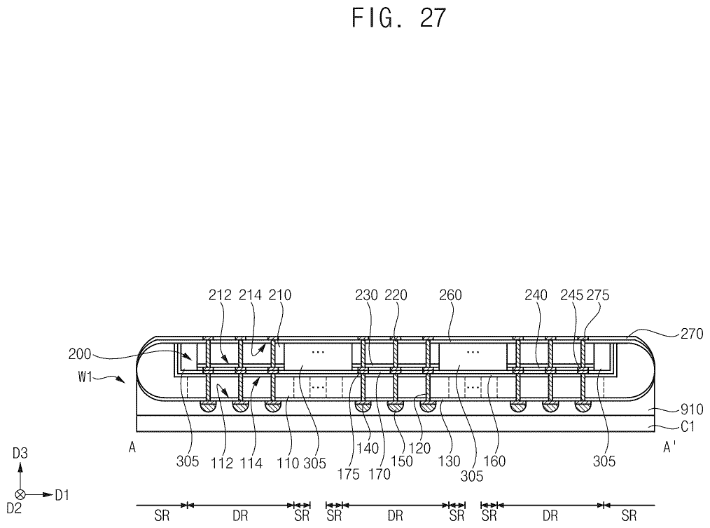

FIGS. 27 to 31 are cross-sectional views illustrating an example of a method of manufacturing a semiconductor package. This method may include processes substantially the same as or similar to those illustrated with reference to FIGS. 21 to 26, and thus repeated explanations thereof are omitted herein.

Referring to FIG. 27, processes substantially the same as or similar to those illustrated with reference to FIGS. 21 to 25 may be performed, and as illustrated above with reference to FIG. 26, the second protective pattern structure 260, the third bonding layer 270 and the third bonding pads 275 may be formed.

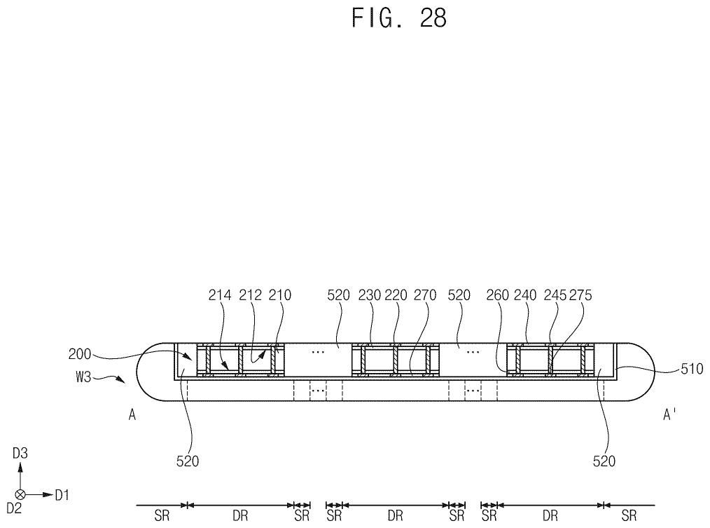

Referring to FIG. 28, a portion of the third wafer W3 may be removed to form a second trench, and a sixth bonding layer 510 may be formed on a sidewall of the second trench and an upper surface of the third wafer W3.

The sixth bonding layer 510 may include an insulating material, e.g., silicon carbonitride, silicon oxide, etc.

Processes substantially the same as or similar to those illustrated with respect to FIGS. 23 to 25 may be performed so that the second semiconductor chips 200 may be mounted on the sixth bonding layer 510 in the second trench, and a fourth filling pattern 520 may be formed between the second semiconductor chips 200.

However, each of the second semiconductor chips 200 may include not only the second substrate 210, the second through electrode structure 220, the third insulating interlayer, the fourth insulating interlayer 230 and the second bonding layer 240 including the second bonding pad 245, but also the second protective pattern structure 260 disposed on the second surface 214 of the second substrate 210 and surrounding a lower portion of the second through electrode structure 220, and the third bonding layer 270 including the third bonding pad 275 may be disposed on the lower surface of the second protective pattern structure 260.

For example, after performing the process illustrated with reference to FIG. 6, a grinding process and/or a CMP process may be further performed on the portion of the second substrate 210 adjacent to the second surface 214 of the second substrate 210 to expose the upper portion of the second through electrode structure 220, the second protective pattern structure 260 may be formed on the second surface 214 of the second substrate 210 to surround the upper portion of the second through electrode structure 220, the third bonding layer 270 including the third bonding pad 275 may be formed on the second protective pattern structure 260 and the second through electrode structure 220, and a sawing process may be performed on the second wafer W2 so that the second wafer W2 may be singulated into a plurality of second semiconductor chips 200.

Each of the second semiconductor chips 200 may be mounted on the second trench such that the third bonding layer 270 may contact the sixth bonding layer 510, and thus the second bonding layer 240 of each of the second semiconductor chips 200 may face upwardly.

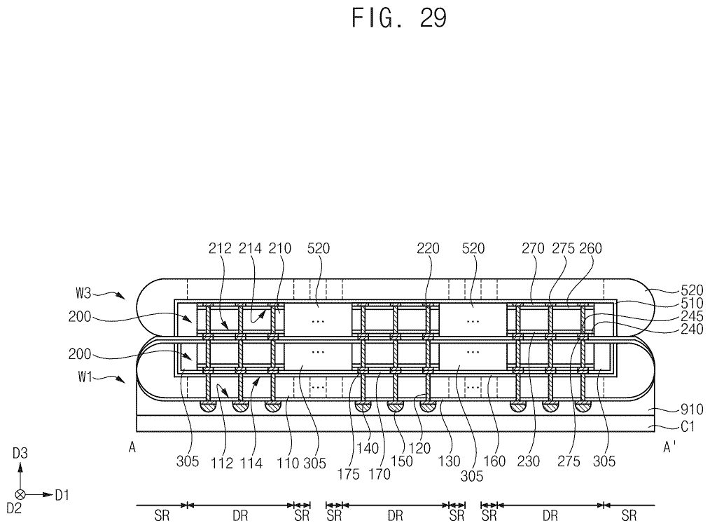

Referring to FIG. 29, after flipping the third wafer W3, the second semiconductor chips 200 and the fourth filling pattern 520 on the third wafer W3 may contact an upper surface of the third bonding layer 270 of the first wafer W1 so that the third wafer W3 may be mounted on the first wafer W1.

The second bonding pads 245 in the second bonding layer 240 in each of the second semiconductor chips 200 mounted on the third wafer W3 may contact the third bonding pads 275 in the third bonding layer 270 on the first wafer W1.

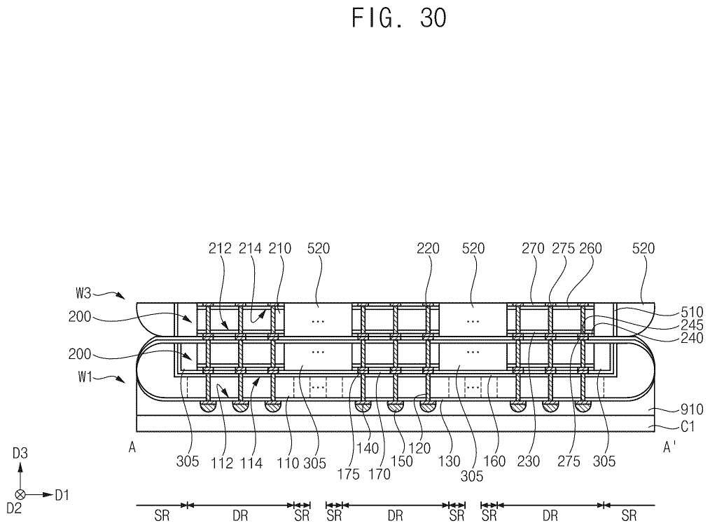

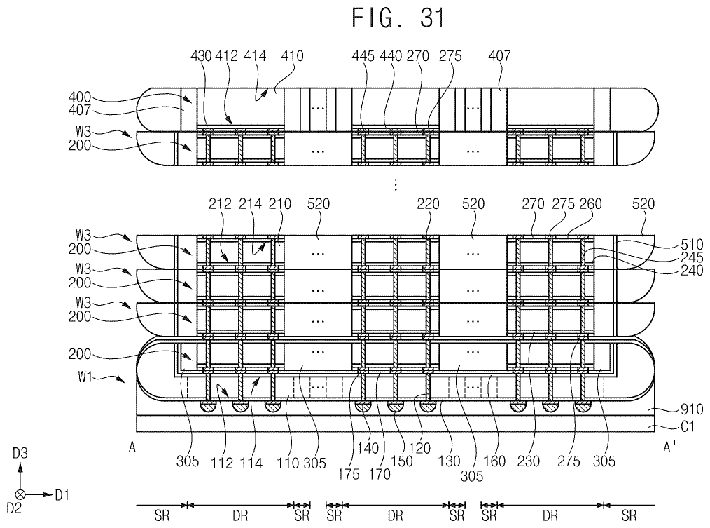

Referring to FIG. 30, a grinding process and/or a CMP process may be performed on an upper surface of the third wafer W3, so that upper surfaces of the third bonding layer 270 and the third bonding pads 275 in each of the second semiconductor chips 200 may be exposed, and upper surfaces of the fourth filling pattern 520 and the sixth bonding layer 510 may also be exposed.

Referring to FIG. 31, processes substantially the same as or similar to those illustrated with respect to FIGS. 28 to 30 may be performed so that a plurality of third wafers W3 and a plurality of second semiconductor chips 200 may be stacked in the third direction D3, and the fourth carrier substrate C4 and the third semiconductor chip 400 may be stacked on the uppermost one of the third carrier substrates C3 and the second semiconductor chips 200.

Processes substantially the same as or similar to those illustrated with respect to FIG. 1 may be performed to complete the manufacturing of the semiconductor package.

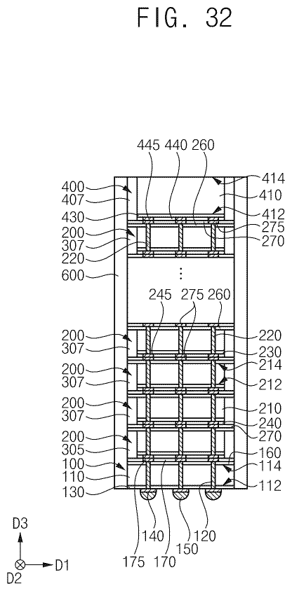

FIG. 32 is a cross-sectional view illustrating an example of a semiconductor package. This semiconductor package may be substantially the same as or similar to that of FIG. 1, except for further including a molding member, and thus repeated explanations are omitted herein.

Referring to FIG. 32, the semiconductor package may include a molding member 600 covering sidewalls of the first semiconductor chip 100, the first and second protective pattern structures 160 and 260, the first and third bonding layer structures 170 and 270, the first to third filling patterns 305, 307 and 407 and the upper surface of the third semiconductor chip 400.

In some implementations, the molding member 600 may include, e.g., epoxy molding compound (EMC).

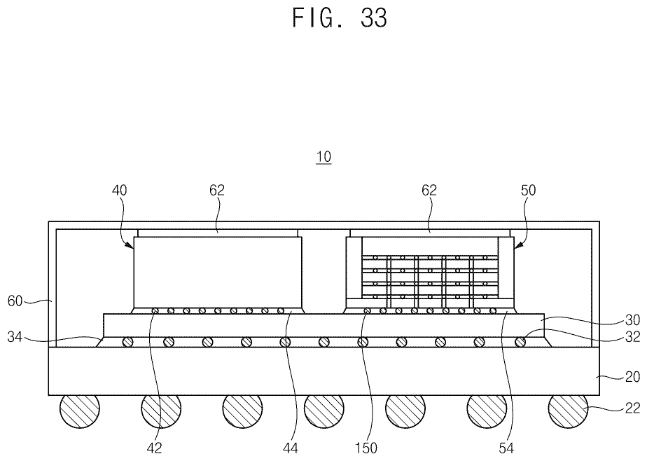

FIG. 33 is a cross-sectional view illustrating an example of an electronic device.

This electronic device may include the semiconductor package shown in FIG. 1 as a second semiconductor device 50.

Referring to FIG. 33, an electronic device 10 may include a package substrate 20, an interposer 30, a first semiconductor device 40 and the second semiconductor device 50. The electronic device 10 may further include first, second and third underfill members 34, 44 and 54, a heat slug 60 and a heat dissipation member 62.

In some implementations, the electronic device 10 may be a memory module having a 2.5D package structure, and thus may include the interposer 30 for electrically connecting the first and second semiconductor devices 40 and 50 to each other.

In some implementations, the first semiconductor device 40 may include a logic device, and the second semiconductor device 50 may include a memory device. The logic device may be an application-specific integrated circuit (ASIC) chip including, e.g., a central processing unit (CPU), a graphics processing unit (GPU), a micro-processor, a micro-controller, an application processor (AP), a digital signal processing core, etc. The memory device may include a semiconductor package such as an HBM package.

In some implementations, the package substrate 20 may have an upper surface and a lower surface opposite to each other in the third direction D3. For example, the package substrate 20 may be a printed circuit board (PCB). The printed circuit board may be a multi-layer circuit board having various circuits therein.

The interposer 30 may be mounted on the package substrate 20 through a third conductive connection member 32. In some implementations, a planar area of the interposer 30 may be smaller than a planar area of the package substrate 20. The interposer 30 may be disposed within an area of the package substrate 20 in a plan view.

The interposer 30 may be a silicon interposer or a redistribution interposer having a plurality of wirings therein. The first semiconductor device 40 and the second semiconductor device 50 may be connected to each other through the wirings in the interposer 30 or electrically connected to the package substrate 20 through the third conductive connection member 32. The third conductive connection member 32 may include, e.g., a micro-bump. The silicon interposer may provide a high-density interconnection between the first and second semiconductor devices 40 and 50.

The first semiconductor device 40 may be disposed on the interposer 30. The first semiconductor device 40 may be mounted on and bonded with the interposer 30 by a flip chip bonding process. In this case, the first semiconductor device 40 may be mounted on the interposer 30 such that an active surface on which conductive pads are formed may face downwardly toward the interposer 30. The conductive pads of the first semiconductor device 40 may be electrically connected to conductive pads of the interposer 30 through an eighth conductive connection member 42. For example, the eighth conductive connection member 42 may include, e.g., a micro-bump.

Alternatively, the first semiconductor device 40 may be mounted on the interposer 30 by a wire bonding process, and in this case, the active surface of the first semiconductor device 40 may face upwardly.

The second semiconductor device 50 may be disposed on the interposer 30, and may be spaced apart from the first semiconductor device 40 in the horizontal direction. The second semiconductor device 50 may be mounted on and bonded with the interposer 30 by, e.g., a flip chip bonding process. In this case, conductive pads of the second semiconductor device 50 may be electrically connected to conductive pads of the interposer 30 by the first conductive connection member 150.

Although a single first semiconductor device 40 and a single second semiconductor device 50 are disposed on the interposer 30, however, the inventive concept may not be limited thereto, and a plurality of first semiconductor devices 40 and/or a plurality of second conductive devices 50 may be disposed on the interposer 30.

In some implementations, the first underfill member 34 may fill a space between the interposer 30 and the package substrate 20, and the second and third underfill members 44 and 54 may fill a space between the first semiconductor device 40 and the interposer 30 and a space between the second semiconductor device 50 and the interposer 30, respectively.

The first to third underfill members 34, 44 and 54 may include a material having a relatively high fluidity to effectively fill a small space between the first and second semiconductor devices 40 and 50 and the interposer 30 and a small space between the interposer 30 and the package substrate 20. For example, each of the first and second underfill members 34, 44 and 54 may include an adhesive containing an epoxy material.

The semiconductor device 50 may include a buffer die and a plurality of memory dies sequentially stacked on the buffer die. The buffer die and the memory dies may be electrically connected to each other by through electrodes, e.g., TSVs, and the through electrodes may be electrically connected to each other by conductive connection members. Data signals and control signals may be transferred to the buffer die and the memory dies by the through electrodes.

In some implementations, the heat slug 60 may be formed on the package substrate 20 to thermally contact the first and second semiconductor devices 40 and 50. The heat dissipation member 62 may be disposed on an upper surface of each of the first and second semiconductor devices 40 and 50, and may include, e.g., thermal interface material (TIM). The heat slug 60 may thermally contact the first and second semiconductor devices 40 and 50 via the heat dissipation member 62.

A conductive pad may be disposed at a lower portion of the package substrate 20, and a second conductive connection member 22 may be disposed on a lower surface of the conductive pad. In some implementations, a plurality of second conductive connection members 22 may be spaced apart from each other in the horizontal direction. The second conductive connection member 22 may be, e.g., a solder ball. The electronic device 10 may be mounted on a module board via the sixth conductive connection members 22 to form a memory module.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations may also be implemented in combination in a single implementation. Conversely, various features that are described in the context of a single implementation may also be implemented in multiple implementations separately or in any suitable subcombination. Moreover, although features may be described above as acting in certain combinations, one or more features from a combination may in some cases be excised from the combination, and the combination may be directed to a subcombination or variation of a subcombination.

The foregoing is illustrative of example implementations and is not to be construed as limiting thereof. Although a few example implementations have been described, those skilled in the art will readily appreciate that many modifications are possible in example implementations without materially departing from the novel teachings and advantages of the present invention. Accordingly, all such modifications are intended to be included within the scope of example implementations as defined in the claims.

What is claimed is:

1. A semiconductor package comprising:
a first semiconductor chip;
a plurality of second semiconductor chips stacked in a vertical direction on the first semiconductor chip;
a first bonding layer structure between the plurality of second semiconductor chips, the first bonding layer structure including a first bonding pad structure; and
a filling pattern contacting at least a portion of each of the plurality of second semiconductor chips and including silicon oxide or polymer, wherein a sidewall of the filling pattern is aligned with a sidewall of the first semiconductor chip in the vertical direction,
wherein the first bonding layer structure includes a first bonding layer and a second bonding layer that are stacked in the vertical direction, the first and second bonding layers contacting each other,
wherein the first bonding pad structure includes a first bonding pad in the first bonding layer and a second bonding pad in the second bonding layer, the first and second bonding pads contacting each other,
wherein the plurality of second semiconductor chips include at least a first chip and a second chip that is positioned higher than the first chip,
wherein the first bonding layer contacts an upper surface of the first chip of the plurality of second semiconductor chips, and
wherein the second bonding layer contacts a lower surface of the second chip of the plurality of second semiconductor chips.

2. The semiconductor package of claim 1, wherein the filling pattern includes the polymer, wherein the polymer includes at least one of benzocyclobutene, polyimide, or imide-phenol resin.

3. The semiconductor package of claim 1, wherein a planar area of the first bonding layer is greater than a planar area of the second bonding layer.

4. The semiconductor package of claim 1, wherein the filling pattern contacts a sidewall of the second bonding layer.

5. The semiconductor package of claim 1, wherein the filling pattern contacts an upper surface of an edge portion of the first bonding layer.

6. The semiconductor package of claim 1, wherein each of the plurality of second semiconductor chips includes:
a substrate having first and second surfaces opposite to each other in the vertical direction;
a protective pattern structure on the second surface of the substrate and contacting a lower surface of the first bonding layer structure; and
a through-electrode structure extending through the substrate and the protective pattern structure.

7. The semiconductor package of claim 6, wherein a planar area of the protective pattern structure is greater than a planar area of the substrate.

8. The semiconductor package of claim 6, wherein the filling pattern contacts a lower surface of an edge portion of the protective pattern structure.

9. The semiconductor package of claim 1, comprising a second bonding layer structure between the first semiconductor chip and the first chip of the plurality of second semiconductor chips, the second bonding layer structure including a second bonding pad structure.

10. The semiconductor package of claim 9, wherein the second bonding layer structure includes a third bonding layer and a fourth bonding layer that are stacked in the vertical direction, the third and fourth bonding layers contacting each other,
wherein the second bonding pad structure includes a third bonding pad in the third bonding layer and a fourth bonding pad in the fourth bonding layer, the third and fourth bonding pads contacting each other,
wherein the third bonding layer contacts an upper surface of the first semiconductor chip, and
wherein the fourth bonding layer contacts a lower surface of a lowermost one of the plurality of second semiconductor chips.

11. The semiconductor package of claim 10, wherein a planar area of the third bonding layer is greater than a planar area of the fourth bonding layer.

12. The semiconductor package of claim 1, further comprising a second bonding layer structure between the first semiconductor chip and the first chip of the plurality of second semiconductor chips,
wherein the first semiconductor chip includes:
a substrate having first and second surfaces opposite to each other in the vertical direction;
a protective pattern structure on the second surface of the substrate and contacting a lower surface of the second bonding layer structure; and
a through-electrode structure extending through the substrate and the protective pattern structure.

13. The semiconductor package of claim 12, wherein a planar area of the protective pattern structure is equal to a planar area of the substrate.

14. The semiconductor package of claim 1, wherein the first bonding layer structure includes silicon carbonitride or silicon oxide, and
wherein the first bonding pad structure includes copper.

15. A semiconductor package comprising:
a first semiconductor chip;
a bonding layer structure positioned on the first semiconductor chip, the bonding layer structure including a bonding pad structure;
a second semiconductor chip positioned on the bonding layer structure, the second semiconductor chip including:
a substrate having first and second surfaces opposite to each other in a vertical direction,
an insulating interlayer on the first surface of the substrate and contacting an upper surface of the bonding layer structure,
a protective pattern structure on the second surface of the substrate, and
a through-electrode structure (i) extending through the substrate, the insulating interlayer, and the protective pattern structure and (ii) contacting the bonding pad structure; and
a filling pattern that (i) is positioned on the bonding layer structure, (ii) contacts a sidewall of the substrate, a sidewall of the insulating interlayer, and a lower surface of the protective pattern structure, and (iii) includes silicon oxide or polymer.

16. The semiconductor package according to claim 15, wherein the filling pattern contacts an upper surface of an edge portion of the bonding layer structure.

17. The semiconductor package according to claim 15, wherein a planar area of the protective pattern structure is equal to a planar area of the first semiconductor chip.

18. A semiconductor package comprising:
a buffer die;
middle core dies stacked on the buffer die in a vertical direction;
a first bonding layer structure between the buffer die and a lowermost one of the middle core dies, the first bonding layer structure including a first bonding pad structure;
a second bonding layer structure between the middle core dies, the second bonding layer structure including a second bonding pad structure;
a third bonding layer structure on an uppermost one of the middle core dies, the third bonding layer structure including a third bonding pad structure;
a top core die positioned on the third bonding layer structure; and
a filling pattern contacting a sidewall of a portion of each of the middle core dies, wherein a sidewall of the filling pattern is aligned with a sidewall of the buffer die in the vertical direction, and the filling pattern includes silicon oxide or polymer.

19. The semiconductor package according to claim 18, wherein the filling pattern contacts an upper surface of an edge portion of the first bonding layer structure or the second bonding layer structure.

20. The semiconductor package according to claim 18, further comprising:
a molding member covering the sidewall of the buffer die, a sidewall of a portion of each of the first bonding layer structure, the second bonding layer structure, and the third bonding layer structure, a sidewall of a portion of each of the middle core dies, the sidewall of the filling pattern, and an upper surface of the top core die.
